(19) United States
(12) Patent Application Publication
(10) Pub. No.: US 2023/0363113 A1
(43) Pub. Date: Nov. 9, 2023

(54) HEAT SINK WITH BULK HEAT ISOLATION

(71) Applicant: Telefonaktiebolaget LM Ericsson (PUBL), Stockholm (SE)

(72) Inventors: Stevin van Wyk, TÄBY (SE); Georg Hellström, Stockholm (SE); Lena Elmfeldt, Bromma (SE)

(21) Appl. No.: 18/004,902

(22) PCT Filed: Jul. 14, 2021
(86) PCT No.: PCT/SE2021/050727

§ 371 Date: Jan. 10, 2023

Related U.S. Application Data
(60) Provisional application No. 63/052,164, filed on Jul. 15, 2020.

(51) Int. Cl. H05K 7/20

(52) U.S. Cl. CPC H05K 7/20409

(57) ABSTRACT

According to some embodiments, a heatsink system comprises a base plate for thermally coupling the heatsink system to two or more heat generating components, wherein at least one of the heat generating components is a first bulk heat source. The heatsink system further comprises a first heatsink integrated thermosiphon coupled to the base plate at a location that dissipates heat from the first bulk heat source and one or more heat dissipating fins coupled to the base plate at a location that dissipates heat from the heat generating components other than the first bulk heat source. The first heatsink integrated thermosiphon is thermally isolated from the one or more heat dissipating fins.

### TECHNICAL FIELD

Particular embodiments relate to cooling of electronic components, and more specifically to bulk heat isolation.

### BACKGROUND

Generally, all terms used herein are to be interpreted according to their ordinary meaning in the relevant technical field, unless a different meaning is clearly given and/or is implied from the context in which it is used. All references to a/an/the element, apparatus, component, means, step, etc. are to be interpreted openly as referring to at least one instance of the element, apparatus, component, means, step, etc., unless explicitly stated otherwise. The steps of any methods disclosed herein do not have to be performed in the exact order disclosed, unless a step is explicitly described as following or preceding another step and/or where it is implicit that a step must follow or precede another step. Any feature of any of the embodiments disclosed herein may be applied to any other embodiment, wherever appropriate. Likewise, any advantage of any of the embodiments may apply to any other embodiments, and vice versa. Other objectives, features, and advantages of the enclosed embodiments will be apparent from the following description.

Electronic components typically generate some heat as electrical energy is partially converted to thermal energy due to the losses in the respective components. It is normally desirable to remove the heat from these components in a rapid and efficient manner, because increased temperature can affect performance, shorten the lifetime, and cause premature failure of many types of electronic components. Power transistors, such as laterally diffused metal oxide silicon (LDMOS) field effect transistors (FETs) commonly used in radio frequency (RF) power amplifiers, are especially susceptible to overheating. These devices typically handle the large part of the power flowing through the amplifier and consequently need to dissipate the most thermal energy. This tends to make them operate at higher temperatures than other amplifier components. In addition, amplifier efficiency tends to drop as the power transistors heat up, producing still more heat to dissipate and higher temperatures. Further, while semiconductor processing and packaging improvements have enabled designers to produce smaller electronic devices that operate at higher power, the associated increased operating temperatures have limited maximum safe power levels.

One traditional method of cooling electronic power devices involves dispersing the heat generated by the device through its support structure, e.g., a metallic flange, and into a heat sink, typically a ceramic or metal material, which, in turn, dissipates the thermal energy to the environment. The device temperature depends on thermal resistance of all of the materials carrying heat away from the active components of the device, typically one or more semiconductor chips.

The ever-increasing speed of computing electronic devices leads to higher heat generation and is further compounded by the requirement that unit size and weight decrease. This means that average unit temperatures are rising and thereby adversely effecting stability in operation and service lifetime and performance. The general solution is to use a large, common heatsink to dissipate the heat contributed by all the components to maintain an acceptable temperature for operation.

FIG. 1 illustrates the various parts of the typical construction of a common heat dissipating structure. In general, a heatsink includes base plate 10 and fins 12. Fins 12 traditionally are mounted to base plate 10 to increase the total heat dissipation and efficiency as compared to base plate 10 alone. Fins 12 are traditionally rectangular in structure and mounted parallel to each other. Base plate 10 may be mounted to an enclosure or device.

Base plate 10 and fins 12a comprise a standard heatsink designed for natural convection. Base plate 10 and fins 12b comprise a variation on the heatsink where fins 12b are designed towards forced convection to be used with, for example, a fan. Base plate 10 and fins 12c comprise a modified version of fins 12a to allow for the air ambient movement to penetrate the heatsink and/or to save weight.

Modifications of these fin designs and fins of alternative shapes are also used to suit particular flow applications. Additional examples are illustrated in FIG. 2.

FIG. 2 illustrates examples of heatsinks that utilize fin types suited to different environments. For example, alternative heatsink geometries are commonly applied in environments where properties such as orientation independence and increased cooling capacity are desired. Fins 12d comprise pin fins and fins 12e comprise diagonal fins.

Some alternatives improve the efficiency of a given plate fin heatsink under natural convection. An example is illustrated in FIG. 3.

FIG. 3 illustrates secondary fins mounted to the tips of the plate fins. The three illustrated examples include a geometry whereby secondary fins are mounted to the tips of the plate fins. A cover plate is then mounted in a location to generate additional flow via enhanced natural convection. The illustrated examples use a chimney effect to generate additional flow through a set of secondary fins and thereby increase thermal efficiency.

The illustrated technology, however, does not offer a large advantage over a conventional natural convection heatsink in either still or fluctuating air flow environments where fluctuating air flow conditions would simply enhance cooling. The fin regions illustrated in FIG. 3 are dimensioned to take advantage of the additional flow and thereby cooling potential generated by the chimney effect. This design is driven by natural convection alone. There currently exist certain challenges. For example, the drive to decrease weight and volume of products requires further advancements in heatsink design. The efficiency of conventional natural convection heatsinks in current applications is low and potential for further optimization is low compared to the desired performance improvement of certain system components.

### SUMMARY

Based on the description above, certain challenges currently exist with cooling electronic components. Certain aspects of the present disclosure and their embodiments may provide solutions to these or other challenges. For example, particular embodiments isolate certain regions from one another, for example, while maintaining the same or better cooling potential for all components.

According to some embodiments, a heatsink system comprises a base plate for thermally coupling the heatsink system to two or more heat generating components, wherein at least one of the heat generating components is a first bulk heat source. The heatsink system further comprises a first heatsink integrated thermosiphon coupled to the base plate at a location that dissipates heat from the first bulk heat source and one or more heat dissipating fins coupled to the base plate at a location that dissipates heat from the heat generating components other than the first bulk heat source. The first heatsink integrated thermosiphon is thermally isolated from the one or more heat dissipating fins.

In particular embodiments, the coupling of the first heatsink integrated thermosiphon to the base plate includes an at least partially thermal isolating mechanical coupler (e.g., one or more of a gasket, air separation, and plastic separation to thermally isolate the heatsink integrated thermosiphon).

In particular embodiments, the heatsink system further comprises a second bulk heat source and a second heatsink integrated thermosiphon coupled to the base plate at a location that dissipates heat from the second bulk heat source. The second heatsink integrated thermosiphon is thermally isolated from the one or more heat dissipating fins.

In particular embodiments, the first heatsink integrated thermosiphon comprises a thermosiphon and one or more heat dissipating fins, and wherein the thermosiphon is coupled to the base plate at a location that dissipates heat from the first bulk heat source and the one or more heat dissipating fins are positioned remotely from the first bulk heat source (e.g., at various locations on a chassis that includes the heatsink system.

According to some embodiments, a heatsink system comprises two or more heat generating components, wherein at least one of the heat generating components is a first bulk heat source. The heatsink system further comprises a first heatsink integrated thermosiphon coupled proximate the first bulk heat source and one or more heat dissipating fins coupled proximate the heat generating components other than the first bulk heat source. The first heatsink integrated thermosiphon is thermally isolated from the one or more heat dissipating fins.

According to some embodiments, a heatsink system comprises two or more heat generating components, wherein at least one of the heat generating components is a first bulk heat source. The heatsink system further comprises a first heatsink integrated thermosiphon coupled proximate the first bulk heat source and one or more heat sinks coupled proximate the heat generating components other than the first bulk heat source. The first heatsink integrated thermosiphon is thermally isolated from the one or more heat sinks.

Certain embodiments may provide one or more of the following technical advantages. For example, particular embodiments include improved thermal cooling without expanding the heat sink footprint or added weight.

### BRIEF DESCRIPTION OF THE DRAWINGS

For a more complete understanding of the disclosed embodiments and their features and advantages, reference is now made to the following description, taken in conjunction with the accompanying drawings, in which:

FIG. 1 illustrates the various parts of the typical construction of a common heat dissipating structure;

FIG. 2 illustrates examples of heatsinks that utilize fin types suited to different environments;

FIG. 3 illustrates secondary fins mounted to the tips of the plate fins;

FIGS. 4A-4D are schematic diagrams illustrating an example heatsink structure, according to particular embodiments; and

FIG. 5 includes schematic diagrams illustrating three additional example heatsink structures, according to particular embodiments.

### DETAILED DESCRIPTION

As described above, certain challenges currently exist with cooling electronic components. Certain aspects of the present disclosure and their embodiments may provide solutions to these or other challenges. For example, particular embodiments isolate certain regions from one another, for example, while maintaining the same or better cooling potential for all components.

Particular embodiments are described more fully with reference to the accompanying drawings. Other embodiments, however, are contained within the scope of the subject matter disclosed herein. The disclosed subject matter should not be construed as limited to only the embodiments set forth herein; rather, these embodiments are provided by way of example to convey the scope of the subject matter to those skilled in the art.

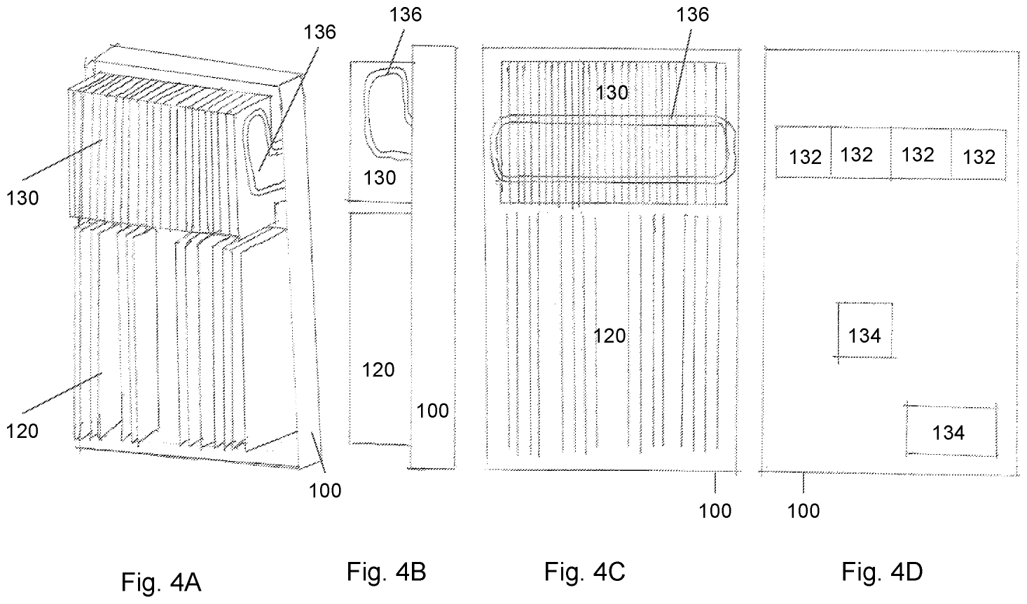

In particular embodiments, heatsinks are structured to isolate bulk heat generating components from the rest of the system while maintaining the required level of cooling locally and resulting in a large benefit to the system. Examples are illustrated in FIGS. 4A-4D.

FIGS. 4A-4D are schematic diagrams illustrating an example heatsink structure where power amplifiers are cooled by a separate heatsink enabled by a heatsink integrated thermosiphon, or thermosiphon heatsink (TSHS), that connects each bulk heat source (e.g., each power amplifier) with the entire TSHS structure. A particular advantage is increased heatsink/system cooling capacity within a given volume constraint and via a limited/small heat transfer path. The TSHS more efficiently dissipates the bulk heat in a defined volume by spreading the heat to all of the fins of the TSHS structure simultaneously and isothermally, while the TSHS is disconnected as much as possible from the rest of the system. Experimentation shows that there is a large thermal/cooling potential for all components that are separated from the isolated section.

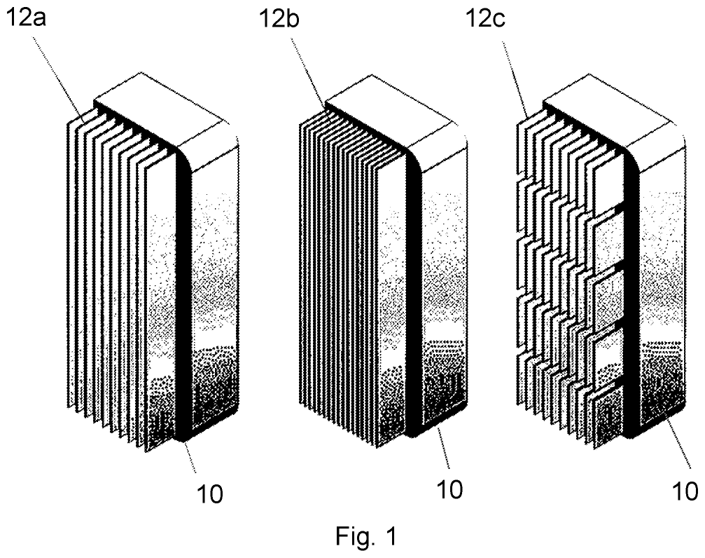

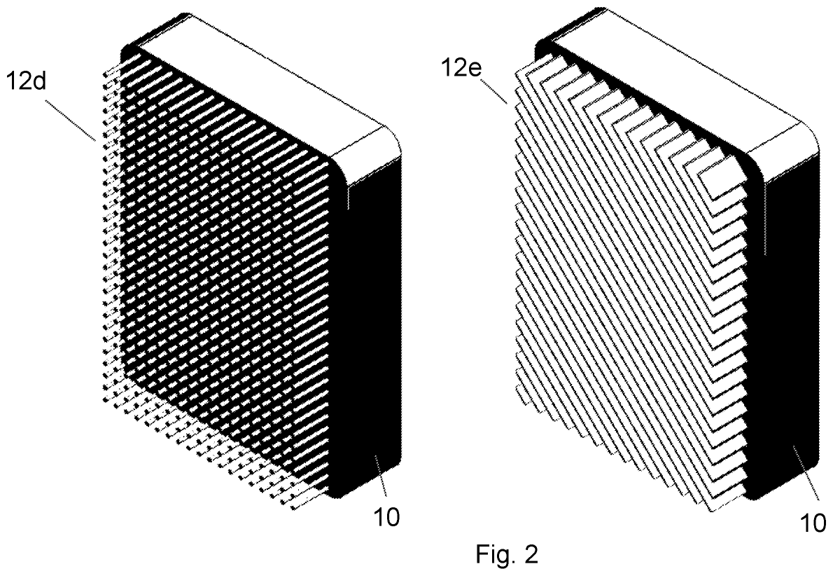

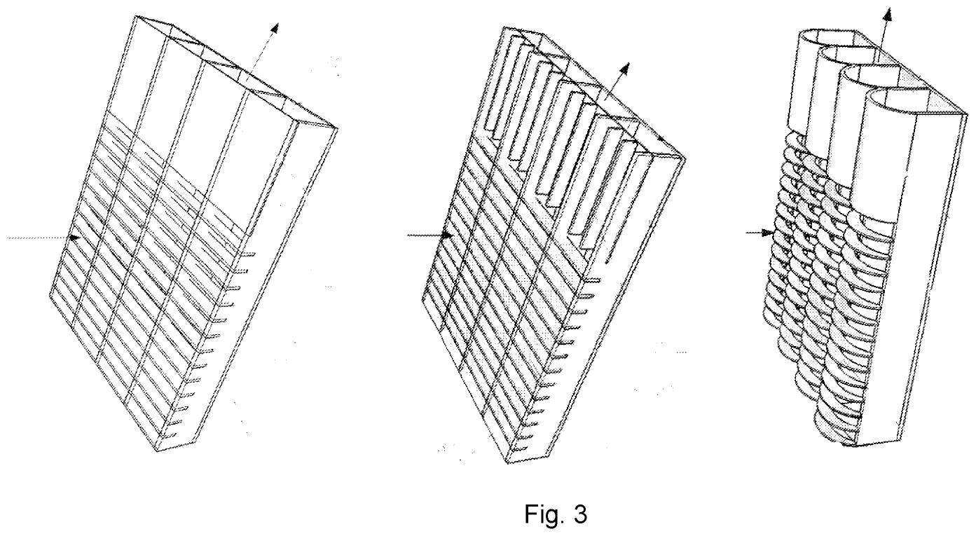

FIG. 4A is a perspective schematic diagram of an example heatsink system. The heatsink system includes fins 120 and TSHS structure 130 coupled to base plate 100. Fins 120 are similar to fins 12 described with respect to FIGS. 1-3.

FIG. 4B is a schematic side view of the example heatsink system. FIG. 4C is a front schematic view, and FIG. 4D is a schematic view of the underside of the example heatsink system.

Thermosiphon Heatsink (TSHS) 130 comprises a plurality of heatsink fins. Each of the plurality of fins includes thermosiphon 136. A thermosiphon is a method of passive heat exchange, based on natural convection, which circulates a fluid, such as water or a refrigerant, without the necessity of a mechanical pump. A thermosiphon uses convection for the movement of heated fluid from the components upwards to a heat exchanger. There the fluid is cooled and is ready to be recirculated. A thermosiphon transports heat with a high degree of efficiency from the component source and can typically maintain the component temperature several degrees cooler than a traditional heatsink.

Thermosiphons 136 of each fin are coupled to each other (as illustrated in FIG. 4C) and the thermosiphon fluid is transported among all of the fins. Thus, heat may be dissipated across the entire TSHS 130. Although a particular TSHS configuration is illustrated, TSHS may come in a variety of tube/cavity structures that transport fluid through a variety of fin structures.

Heatsink integrated thermosiphon 130 may be coupled to base plate 100 at a location where heatsink integrated thermosiphon 130 may dissipate heat from a bulk heat source. For example, the underside of the example heatsink system illustrated in FIG. 4D includes contact points 132 where the heatsink system contacts bulk heat sources, such as power amplifiers. The underside of the heatsink system may also include contact points 134 where the heatsink system contacts components, such as processors, that generate less heat than the bulk heat sources.

Accordingly, as illustrated in FIGS. 4A-4C, heatsink integrated thermosiphon 130 is positioned above contact points 132, and fins 120 are positioned above contact points 134. Heatsink integrated thermosiphon 130 is thermally isolated from the other components of the heatsink system, such as fins 120. Accordingly, heatsink integrated thermosiphon 130 dissipates heat from the bulk heat sources without spreading the heat to fins 120. Fins 120 are able to cool the other components more efficiently because fins 120 do not have to dissipate the heat from the bulk heat components.

Heatsink integrated thermosiphon 130 may be mechanically coupled to base plate 100 using thermal isolation. For example, any combination of gaskets, plastic separation, air gapped separation in combination with mechanical fasteners may be used to couple heatsink integrated thermosiphon 130 to base plate 100.

In some embodiments, heatsink integrated thermosiphon 130 makes partial thermal contact with base plate 100 where there may be a thin layer of base plate 100 between contact points 132 and heatsink integrated thermosiphon 130. Even so, heatsink integrated thermosiphon 130 still transports/isolates most heat away from fins 120. This is because he thermal resistance towards heatsink integrated thermosiphon 130 is low enough that most heat wants to move there anyway. Thus, some embodiments may make metal contact through a base plate layer, spreading a small amount of heat to fins 120, but still obtaining a large degree of system isolation. The TSHS is a powerful isolating structure/component even without total/ideal thermal isolation.

The heatsink system illustrated in FIGS. 4A-4D is one example. Other embodiments may include other configurations.

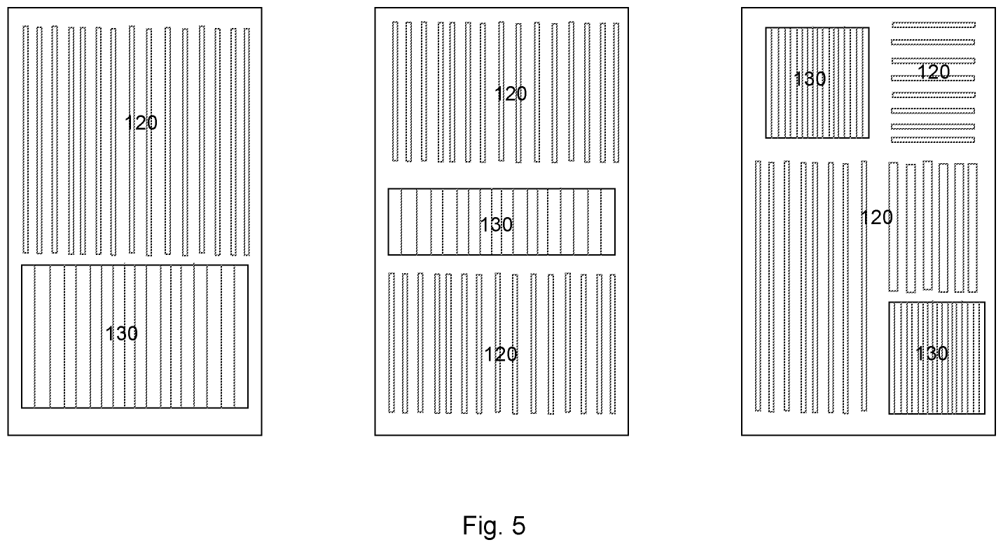

FIG. 5 illustrates three additional examples, where fins 120 and heatsink integrated thermosiphon 130 are positioned in different locations, based on the location of the underlying bulk heat sources for a particular application. Some embodiments may include more than one heatsink integrated thermosiphon 130. Although the examples are illustrated in vertical position, particular embodiments may include horizontal heatsink systems.

In some embodiments, the heat can be moved to any external heatsink/chassis location from within the system. For example, in some embodiments the heatsink system may be part of a larger chassis that includes multiple circuit boards. The heatsink integrated thermosiphon may move the heat to the front, back or top of the chassis (e.g., the heat dissipating fins of the integrated thermosiphon may be remote from the bulk heat source).

Multiple heatsink fins (and the integrated thermosiphon loops in fins) may be interconnected at/from any heat source location, where the heat source is even far from the heatsink fins (where the heat is dissipated) that are a part of the heatsink integrated thermosiphon. An advantage is that the heat can be transported over large distances without any decrease in the heatsink dissipation efficiency. This also means that the size/length of the heatsink parts (thermosiphon loops and fins) of the heatsink integrated thermosiphon can potentially be unlimited in size, while still maintaining maximum thermal efficiency (isothermal behavior).

While several embodiments are described herein, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

Modifications, additions, or omissions may be made to the systems and apparatuses disclosed herein without departing from the scope of the invention. The components of the systems and apparatuses may be integrated or separated. Moreover, the operations of the systems and apparatuses may be performed by more, fewer, or other components. Additionally, operations of the systems and apparatuses may be performed using any suitable logic comprising software, hardware, and/or other logic. As used in this document, “each” refers to each member of a set or each member of a subset of a set.

Modifications, additions, or omissions may be made to the methods disclosed herein without departing from the scope of the invention. The methods may include more, fewer, or other steps. Additionally, steps may be performed in any suitable order.

The foregoing description sets forth numerous specific details. It is understood, however, that embodiments may be practiced without these specific details. In other instances, well-known circuits, structures and techniques have not been shown in detail in order not to obscure the understanding of this description. Those of ordinary skill in the art, with the included descriptions, will be able to implement appropriate functionality without undue experimentation.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to implement such feature, structure, or characteristic in connection with other embodiments, whether or not explicitly described.

Although this disclosure has been described in terms of certain embodiments, alterations and permutations of the embodiments will be apparent to those skilled in the art. Accordingly, the above description of the embodiments does not constrain this disclosure. Other changes, substitutions, and alterations are possible without departing from the scope of this disclosure, as defined by the claims below.

1. A heatsink system comprising:
a base plate for thermally coupling the heatsink system to two or more heat generating components, wherein at least one of the heat generating components comprises a first bulk heat source;
a first heatsink integrated thermosiphon coupled to the base plate at a location that dissipates heat from the first bulk heat source;
one or more heat dissipating fins coupled to the base plate at a location that dissipates heat from the heat generating components other than the first bulk heat source; and
wherein the first heatsink integrated thermosiphon is thermally isolated from the one or more heat dissipating fins.

2. The heatsink system of claim 1, wherein the coupling of the first heatsink integrated thermosiphon to the base plate includes an at least partially thermal isolating mechanical coupler.

3. The heatsink system of claim 2, wherein the mechanical coupling of the first heatsink integrated thermosiphon to the base plate includes one or more of a gasket, air separation, and plastic separation to thermally isolate the heatsink integrated thermosiphon.

4. The heatsink system of claim 1, further comprising:
a second bulk heat source;
a second heatsink integrated thermosiphon coupled to the base plate at a location that dissipates heat from the second bulk heat source; and
wherein the second heatsink integrated thermosiphon is thermally isolated from the one or more heat dissipating fins.

5. The heatsink system of claim 1, wherein the first heatsink integrated thermosiphon comprises a thermosiphon and one or more heat dissipating fins, and wherein the thermosiphon is coupled to the base plate at a location that dissipates heat from the first bulk heat source and the one or more heat dissipating fins are positioned remotely from the first bulk heat source.

6. A heatsink system comprising:
two or more heat generating components, wherein at least one of the heat generating components comprises a first bulk heat source;
a first heatsink integrated thermosiphon coupled proximate the first bulk heat source;
one or more heat dissipating fins coupled proximate the heat generating components other than the first bulk heat source; and
wherein the first heatsink integrated thermosiphon is thermally isolated from the one or more heat dissipating fins.

7. The heatsink system of claim 6, wherein the coupling of the first heatsink integrated thermosiphon proximate the first bulk heat source includes an at least partially thermal isolating mechanical coupler.

8. The heatsink system of claim 7, wherein the mechanical coupling of the first heatsink integrated thermosiphon proximate the first bulk heat source includes one or more of a gasket, air separation, and plastic separation to thermally isolate the heatsink integrated thermosiphon.

9. The heatsink system of claim 6, further comprising:
a second bulk heat source;
a second heatsink integrated thermosiphon coupled proximate the second bulk heat source; and
wherein the second heatsink integrated thermosiphon is thermally isolated from the one or more heat dissipating fins.

10. The heatsink system of claim 6, wherein the first heatsink integrated thermosiphon comprises a thermosiphon and one or more heat dissipating fins, and wherein the thermosiphon is coupled proximate the first bulk heat source and the one or more heat dissipating fins are positioned remotely from the first bulk heat source.

11. A heatsink system comprising:
two or more heat generating components, wherein at least one of the heat generating components comprises a first bulk heat source;
a first heatsink integrated thermosiphon coupled proximate the first bulk heat source;
one or more heat sinks coupled proximate the heat generating components other than the first bulk heat source; and
wherein the first heatsink integrated thermosiphon is thermally isolated from the one or more heat sinks.

12. The heatsink system of claim 11, wherein the coupling of the first heatsink integrated thermosiphon proximate the first bulk heat source includes an at least partially thermal isolating mechanical coupler.

13. The heatsink system of claim 12, wherein the mechanical coupling of the first heatsink integrated thermosiphon proximate the first bulk heat source includes one or more of a gasket, air separation, and plastic separation to thermally isolate the heatsink integrated thermosiphon.

14. The heatsink system of claim 11, further comprising:
a second bulk heat source;
a second heatsink integrated thermosiphon coupled proximate the second bulk heat source; and
wherein the second heatsink integrated thermosiphon is thermally isolated from the one or more heat sinks.

15. The heatsink system of claim 11, wherein the first heatsink integrated thermosiphon comprises a thermosiphon and one or more heat dissipating fins, and wherein the thermosiphon is coupled proximate the first bulk heat source and the one or more heat dissipating fins are positioned remotely from the first bulk heat source.
